(19) United States
(12) Patent Application Publication
(10) Pub. No.: US 2006/0045970 A1
(43) Pub. Date: Mar. 2, 2006

(54) ALD thin film deposition apparatus and thin film deposition method using same

(76) Inventors: Jung-Hun Seo, Gyeonggi-do (KR); Young-Wook Park, Gyeonggi-do (KR); Jin-Gi Hong, Gyeonggi-do (KR); Eun-Taeck Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/216,431

(22) Filed: Aug. 30, 2005

(30) Foreign Application Priority Data
Aug. 31, 2004 (KR) 10-2004-0068978

(51) Int. Cl. C23C 16/00

(52) U.S. Cl. 427/248.1; 118/715

(57) ABSTRACT

An atomic layer deposition (ALD) thin film deposition apparatus is provided. The atomic layer deposition (ALD) thin film deposition apparatus comprises a reactor including a support on which at least one substrate is placed and a member from which gases are sprayed, a first reaction gas supply line which is coupled with a first reaction gas supply portion which allows a first reaction gas to flow from the first reaction gas supply portion to the reactor, a second reaction gas supply line which is coupled with a second reaction gas supply portion which allows a second reaction gas to flow from the second reaction gas supply portion to the reactor for reacting with the first reaction gas, a purge gas supply line which is coupled with a purge gas supply portion and allows a purge gas to flow from the purge gas supply portion to the reactor for conducting a purge step, and an exhaust line which exhausts a gas from within the reactor to a location outside the reactor. An ALD thin film deposition method is also provided.

This application claims priority from Korean Patent Application No. 10-2004-0068978 filed on Aug. 31, 2004 in the Korean Intellectual Property Office, the disclosure of which is incorporated herein by reference in its entirety.

### BACKGROUND OF THE INVENTION

1. Field of the Invention

The present invention relates to an atomic layer deposition (ALD) thin film deposition apparatus and a thin film deposition method using same, and more particularly, to an ALD thin film deposition apparatus having high thin film deposition efficiency and a thin film deposition method using same.

2. Description of the Related Art

Generally, thin films are importantly used in various technical fields including dielectric layers of semiconductor devices, transparent electrodes of liquid crystal display devices, in protection layers of electroluminescent thin film displays, and the like. Chemical vapor deposition (CVD), atomic layer epitaxy (ALE), atomic layer deposition (ALD) or the like are used as a thin film deposition method.

In particular, an ALD thin film deposition method is a surface controlled process which results in two-dimensional layer-by-layer deposition. ALD thin film deposition is conducted in a surface kinetic regime, thereby ensuring excellent step coverage.

Further, reaction gases are supplied periodically and a chemical exchange of the reaction gases is achieved so that the density of a thin film is very high. Further, since by-products generated in an ALD thin film deposition process are always gases, it is easy to remove the by-products using an exhaust line. Since only a temperature is a variable in the ALD thin film deposition method, it is easy to control the ALD thin film deposition method.

Highly integrated semiconductor devices are needed to reduce the per-wafer cost of producing semiconductor devices. To achieve this, a very thin conductive thin film like an electrode of a capacitor is needed. Accordingly, it is desirable to develop an ALD thin film deposition apparatus capable of depositing a conductive thin film having excellent step coverage and a thin film deposition method using same.

### SUMMARY OF THE INVENTION

An atomic layer deposition (ALD) thin film deposition apparatus is provided. The ALD comprises a reactor including a support for placing at least one substrate is placed thereon and a member from which gases are sprayed. A first reaction gas supply line is coupled with a first reaction gas supply portion which allows a first reaction gas to flow from the first reaction gas supply portion to the reactor. A second reaction gas supply line is coupled with a second reaction gas supply portion which allows a second reaction gas to flow from the second reaction gas supply portion to the reactor for reacting with the first reaction gas. A purge gas supply line is coupled with a purge gas supply portion and allows a purge gas to flow from the purge gas supply portion to the reactor for conducting a purge step. An exhaust line exhausts a gas from within the reactor to a location outside the reactor. Preferably, the support and the member are separated by a predetermined distance of from about 5 mm to about 25 mm.

The purge gas supply line preferably is connected to the first reaction gas supply line and/or the second reaction gas supply line. Preferably, the purge gas supply line is directly connected to the reactor.

The first reaction gas preferably comprises TiCl₄ or Ta and the second reaction gas comprises NH₃. The first reaction gas supply portion can also include a bubbler for gasifying a first reactive material, a first reaction gas mass flow controller (MFC) for controlling the flow rate of the first reaction gas, and a first valve which is placed between the bubbler and the first reaction gas MFC and enables or disables the flow of the first reaction gas. The first reaction gas supply portion can further include a second valve which is placed between the first reaction gas MFC and the reactor on the first reaction gas supply line and enables or disables the flow of the first reaction gas controlled by the first reaction gas MFC.

The second reaction gas supply portion preferably includes a third valve for enabling or disabling the flow of the second reaction gas and a second reaction gas MFC for controlling the flow rate of the second reaction gas passing through the third valve. More preferably, the second reaction gas supply portion further includes a fourth valve which is placed between the second reaction gas MFC and the reactor on the second reaction gas supply line and enables or disables the flow of the second reaction gas controlled by the second reaction gas MFC.

The ALD can further comprise a first inert gas supply line which is connected with a first inert gas supply portion and allows an inert gas to flow from the first inert gas supply portion to the first reaction gas supply line. The first inert gas supply portion preferably includes a fifth valve for enabling or disabling the flow of an inert gas and a first inert gas MFC for controlling the flow rate of the inert gas passing through the fifth valve. More preferably, the first inert gas supply portion further includes a sixth valve which is placed close to the reactor between the first inert gas MFC and the reactor on the first inert gas supply line and enables or disables the flow of an inert gas controlled by the first inert gas MFC.

The ALD can further comprise a second inert gas supply line which is coupled with a second inert gas supply portion and allows an inert gas to flow from the second inert gas supply portion to the second reaction gas supply line. Preferably, the second inert gas supply portion includes a seventh valve for enabling or disabling the flow of an inert gas and a second inert gas MFC for controlling the flow rate of the inert gas passing through the seventh valve. More preferably, the second inert gas supply portion further includes an eighth valve which is placed between the second inert gas MFC and the reactor on the second inert gas supply line and enables or disables the flow of an inert gas controlled by the second reaction gas MFC.

The ALD can further comprise a first bypass line which includes a ninth valve for enabling or disabling the flow of the first reaction gas and allows the first reaction gas to flow directly to the exhaust line without passing through the reactor. The ALD can also comprise a second bypass line which includes a tenth valve for enabling or disabling the flow of the second reaction gas and allows the second reaction gas to flow directly to the exhaust line without passing through the reactor. The flow rates of the purge gas supplied to the first reaction gas supply line and the second reaction gas supply line are preferably independently controlled by a first purge gas MFC and a second purge gas MFC, respectively, placed on the purge gas supply line.

The purge gas supply portion can further include an eleventh valve and a twelfth valve which are placed close to the reactor at an interval of a predetermined distance on the first reaction gas supply line and the second reaction gas supply line, and enable or disable the flow of the purge gas controlled respectively by the first purge gas MFC and the second purge gas MFC. The purge gas supply portion preferably further includes a pressure adjusting portion which is placed between the first purge gas MFC and the second purge gas MFC and a purge gas supply source and constantly maintains a pressure of an output end.

A first connecting portion for connecting the first reaction gas supply line and/or the second reaction gas supply line to the purge gas supply line is preferably placed adjacent to a second connecting portion for connecting the first reaction gas supply line and/or the second reaction gas supply line to the reactor at a predetermined distance. The predetermined distance is preferably from about 20 cm to about 50 cm.

The eleventh and twelfth valves are preferably placed adjacent to the first connecting portion at an interval of a predetermined distance. The predetermined distance is preferably from about 20 cm to about 40 cm.

The purge gas is preferably N₂ and/or Ar and/or Ne. The ALD can further comprise a third bypass line which includes a thirteenth valve for enabling or disabling the flow of the purge gas and allows the purge gas to flow directly to the exhaust line without passing through the reactor.

The first reaction gas supply portion preferably includes a valve for enabling or disabling the flow of the first reaction gas and a first reaction gas MFC for controlling the flow rate of the first reaction gas passing through the valve. The first reaction gas is preferably WF₆ and the second reaction gas is NH₃.

The ALD can further comprise a third reaction gas supply line which is coupled with a third reaction gas supply portion and allows a third reaction gas to flow from the third reaction gas supply portion to the reactor exclusively with respect to the first reaction gas, It can also include a fourth reaction gas supply line which is connected with a fourth reaction gas supply portion and allows a fourth reaction gas to flow from the fourth reaction gas supply portion to the reactor exclusively with respect to the first reaction gas. The third reaction gas supply line and the fourth reaction gas supply line are preferably connected to the second reaction gas supply line. The third reaction gas supply portion preferably includes a bubbler for gasifying a third reactive material, a third reaction gas MFC for controlling the flow rate of the third reaction gas, and a first valve which is placed between the bubbler and the third reaction gas MFC and enables or disables the flow of the third reaction gas. The fourth reaction gas supply portion can further include a second valve for enabling or disabling the flow of the fourth reaction gas and a fourth reaction gas MFC for controlling the flow rate of the fourth reaction gas passing through the second valve. The third reaction gas is preferably trimethylaluminum (TMA) and the fourth reaction gas is preferably H₂.

An ALD thin film deposition method can be provided which comprises, placing at least one substrate on a support located within a reactor, providing a member located within the reactor from which gases are sprayed, supplying a first reaction gas to the reactor through a first reaction gas supply line, supplying a first purge gas to the reactor through a purge gas supply line to the first reaction gas, supplying a second reaction gas to the reactor through a second reaction gas supply line for reaction with the first reaction gas, and supplying a second purge gas to the reactor through the purge gas supply line to the second reaction gas. The method preferably comprises supplying of the first reaction gas, the first purge gas, the second reaction gas and the second purge gas includes supplying an inert gas to the reactor through an inert gas supply line. The purge gas is preferably supplied at a flow rate of from about 500 sccm to about 10,000 sccm. The flow rates of the inert gas and the purge gas are preferably at least about two times greater than the flow rate of the first reaction gas or the flow rate of the second reaction gas. The supply time for providing the purge gas is preferably from about 0.2 seconds to about 4 seconds.

### BRIEF DESCRIPTION OF THE DRAWINGS

The above and other features and advantages of the present invention will become more apparent by describing in detail preferred embodiments thereof with reference to the attached drawings in which:

FIG. 1 illustrates an atomic layer deposition (ALD) thin film deposition apparatus according to one embodiment of the present invention;

FIG. 2 is a graph showing changes in specific resistance and a deposition rate according to an increase in the flow rate of an inert gas;

FIG. 3 is a graph showing changes in a deposition speed according to the duration of supply time of a first reaction gas;

FIGS. 4A and 4B are graphs showing changes in a deposition speed according to the duration of supply time of first and second reaction gases when a process pressure within a reactor is reduced;

FIGS. 5A and 5B are graphs showing changes in a deposition speed according to the duration of supply time of the first and second reaction gases under conditions of Table 3;

FIGS. 6A and 6B are graphs showing changes in a deposition speed according to the duration of supply time of the first and second reaction gases when using the ALD thin film deposition apparatus according to one embodiment of the present invention;

FIG. 7 is a cross-sectional view of an upper electrode of a capacitor fabricated using the ALD thin film deposition apparatus according to one embodiment of the present invention;

FIG. 8A is a flowchart showing an ALD thin film deposition method using the ALD thin film deposition apparatus according to one embodiment of the present invention;

FIG. 8B is a diagram for schematically explaining the supply of gas in the ALD thin film deposition method according to one embodiment of the present invention;

FIG. 9 illustrates an ALD thin film deposition apparatus according to another embodiment of the present invention; and

FIG. 10 illustrates an ALD thin film deposition apparatus according to still another embodiment of the present invention.

### DETAILED DESCRIPTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

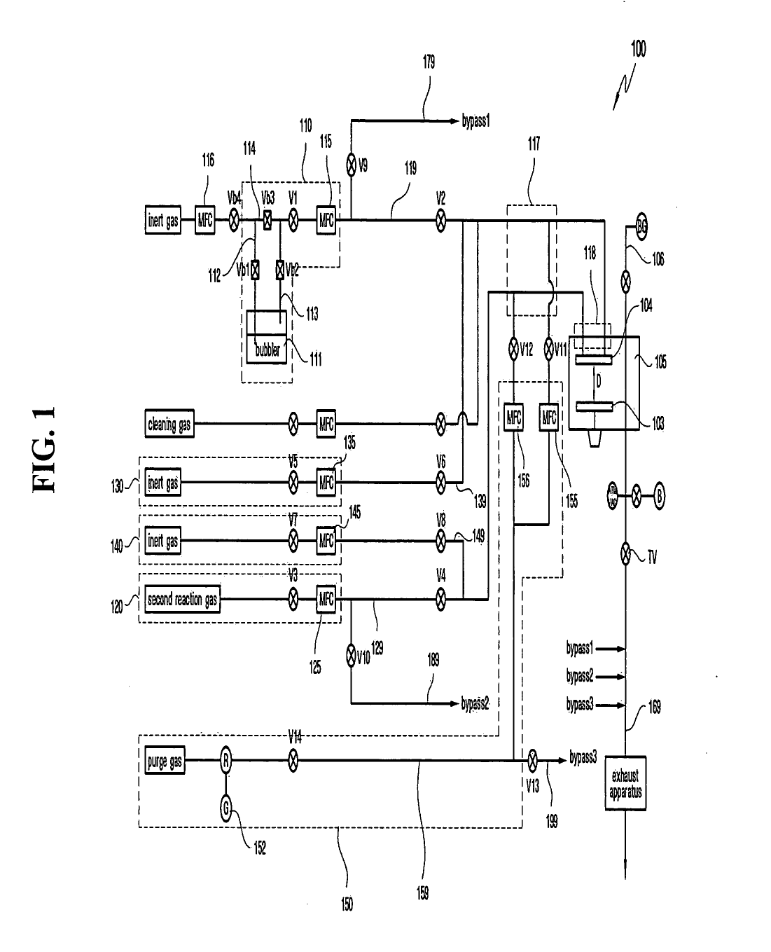

Referring FIG. 1, the ALD thin film deposition apparatus 100 includes a reactor 105, a first reaction gas supply portion 110, a first reaction gas supply line 119, a second reaction gas supply portion 120, a second reaction gas supply line 129, first and second inert gas supply portions 130 and 140, a first inert gas supply line 139, a second inert gas supply line 149, a purge gas supply portion 150, a purge gas supply line 159 and an exhaust line 169.

TiN and TaN thin films can be deposited using the ALD thin film deposition apparatus 100 according to this embodiment of the present invention. In this case, a first reaction gas is a compound gas containing TiCl₄ or Ta, and a second reaction gas is NH₃. However, the present invention is not limited to these gases and different gases can easily be selected by those of ordinary skill in the art to which the present invention pertains.

A thin film deposition process is performed on one or more substrates placed within the reactor 105.

The reactor 105 includes a diffusion plate 104 for spraying a reaction gas and a substrate block 103 on which the substrates are placed. In particular, an interval D between the diffusion plate 104 and the substrate block 103 of the reactor 105 is much smaller than that of a chemical vapor deposition (CVD) thin film deposition apparatus. That is, while an interval D in the CVD thin film deposition apparatus is in the range of about 40-100 mm, the interval D in the ALD thin film deposition apparatus 100 is in the range of about 5-25 mm.

That is, a dense first reaction gas layer is formed on the substrate by a spray pressure of the first reaction gas and/or an inert gas supplied to the reactor 105. The dense first reaction gas layer reacts with the second reaction gas which is to be supplied later so that a thin film with excellent electrical properties can be formed.

Further, the pressure inside the reactor 105 is maintained within the range of 1-10 torr. In order to control the internal pressure, a pressure measuring portion 106 is needed.

The inside of the reactor 105 is preferably maintained at a temperature of from about 100° C. up to about 250° C., the diffusion plate 104 is preferably maintained at a temperature of from about 130° C. up to about 300° C. and the substrate block 103 is preferably maintained at a temperature of from about 400° C. up to about 650° C. In order to control these temperatures, a plurality of heaters (not shown) can be employed.

The first reaction gas supply portion 110 includes a bubbler 111 for gasifying a first reactive material, a first reaction gas mass flow controller (MFC) 115 for controlling the flow rate of the first reaction gas, and a first valve V1 which is placed between the bubbler 111 and the first reaction gas MFC 115 which can enable and disable the flow of the first reaction gas.

The bubbler 111 includes a canister (not shown), b1, b2 and b3 valves Vb1, Vb2 and Vb3 and b1, b2 and b3 gas lines 112, 113 and 114. The first reactive material can be received in the canister in a liquid state. For example, TiCl₄, trimethylaluminum (TMA; Al(CH₃)₃), or the like, can be received in a liquid state. TiCl₄, will be used as the first reactive material for exemplary purposes.

An inert gas is supplied through the b1 gas line 112 Ar, Ne, N₂, or the like, are mainly used as the inert gas; however, the inert gas is not limited to these gases. The inert gas is supplied from an inert gas supply source and the flow rate of the inert gas is controlled by a b1 inert gas controller MFC 116. Further, enabling and disabling the flow of the inert gas is controlled by a b4 valve Vb4.

The b1 valve Vb1 is placed on the b1 gas line 112 and enables or disables the flow of the supplied inert gas. Generally, an air valve is used as the b1 valve Vb1.

Bubbled TiCl₄ gas is supplied to the first reaction gas supply line 119 through the b2 gas line 113. The b2 valve Vb2 is located on the b2 gas line 113 and enables or disables the flow of TiCl₄ gas.

The b3 gas line 114 allows an inert gas to be directly supplied to the first reaction gas supply line 119 rather than the bubbler 111. The inert gas directly supplied to the first reaction gas supply line 119 is mainly used in a purge step. The b3 valve Vb3 is placed on the b3 gas line 114 and enables or disables the flow of an inert gas.

The first reaction gas supply line 119 connects the first reaction gas supply portion 110 to the reactor 105. Further, a first inert gas supply line 139 which supplies an inert gas for helping the movement of the first reaction gas or diluting the first reaction gas is connected to the first reaction gas supply line 119. A first bypass line 179 for allowing the first reaction gas to flow directly to the exhaust line 169 without passing through the reactor 105 is connected to the first reaction gas supply line 119.

The first reaction gas supply line 119 may further include a second valve V2 for enabling or disabling the flow of the first reaction gas controlled by the first reaction gas MFC 115. The second valve V2 is placed between the first reaction gas MFC 115 and the reactor 105 and is preferably close to the diffusion plate 104 of the reactor 105. That is, since the first reaction gas is introduced into the reactor 105 according to on/off operations of the second valve V2, it is desirable for the distance between the last valve and the reactor 105 to be as short as possible. Preferably, the distance between the second valve V2 and the reactor 105 is from about 20 cm up to about 50 cm.

The second reaction gas supply portion 120 includes a third valve V3 for enabling or disabling the flow of the second reaction gas and a second reaction gas MFC 125 for controlling the flow rate of the second reaction gas passing through the third valve V3.

The second reaction gas supply line 129 connects the second reaction gas supply portion 120 to the reactor 105. Further, a second inert gas supply line 149 for supplying an inert gas is connected to the second reaction gas supply line 129. A second bypass line 189 for allowing the second reaction gas to flow directly to the exhaust line 169 without passing through the reactor 105 is connected to the second reaction gas supply line 129.

The second reaction gas supply line 129 may further include a fourth valve V4 for enabling or disabling the flow of the second reaction gas controlled by the second reaction gas MFC 125. The fourth valve V4 is placed between the second reaction gas MFC 125 and the reactor 105 and is preferably close to the diffusion plate 104 of the reactor 105. The distance between the fourth valve V4 and the reactor 105 is from about 20 cm up to about 50 cm.

The first bypass line 179 allows the first reaction gas to flow directly to the exhaust line 169 without passing through the reactor 105. The first bypass line 179 may further include a ninth valve V9 for enabling or disabling the flow of the first reaction gas. The second bypass line 189 allows the second reaction gas to flow directly to the exhaust line 169 without passing through the reactor 105. The second bypass line 189 may further include a tenth valve V10 for enabling or disabling the flow of the second reaction gas.

The first and second bypass lines 179 and 189 are designed to carry a small amount of air introduced when replacing a raw material of the first reaction gas or the second reaction gas directly to the exhaust line 169 without passing through the reactor 105. Otherwise, the first and second bypass lines 179 and 189 are designed to replace some of a plurality of gas supply lines when the gas supply lines are contaminated. That is, an inert gas allows the first and second reaction gases, air, contaminants or the like, which exist in the gas supply lines, to be directly removed to the exhaust line 169 through the first and second bypass lines 179 and 189, thereby making it possible to prevent the reactor 105 from being contaminated.

This embodiment of the present invention comprises first and second inert gas supply portions 130 and 140. However, those skilled in the art to which the present invention pertains could use only one inert gas supply portion without departing from the spirit and scope of the present invention. Of course, the number of supply portions supplying an inert gas to the bubbler 111 may be one. Hereinafter, the first inert gas supply portion 130 and the second inert gas supply portion 140 will be described separately.

The first inert gas supply portion 130 includes a fifth valve V5 for enabling or disabling the flow of an inert gas, a first inert gas MFC 135 for controlling the flow rate of the inert gas passing through the fifth valve V5, and a sixth valve V6 for enabling or disabling the flow of the inert gas controlled by the first inert gas MFC 135. The sixth valve V6 is placed between the first inert gas MFC 135 and the reactor 105 and it is advantageous for the sixth valve V6 to be as close as possible to the diffusion plate 104 of the reactor 105. A distance between the sixth valve V6 and the reactor 105 is from about 20 cm up to about 50 cm.

The second inert gas supply portion 140 includes a seventh valve V7 for enabling or disabling the flow of an inert gas, a second inert gas MFC 145 for controlling the flow rate of the inert gas passing through the seventh valve V7, and an eighth valve V8 for enabling or disabling the flow of the inert gas controlled by the second inert gas MFC 145. The eighth valve V8 is placed between the second inert gas MFC 145 and the reactor 105 and it is advantageous for the eighth valve V8 to be as close as possible to the diffusion plate 104 of the reactor 105. The distance between the eighth valve V8 and the reactor 105 is from about 20 cm up to about 50 cm.

Generally, an inert gas is continuously introduced into the reactor 105 during the ALD thin film deposition process. An inert gas is supplied to the first reaction gas supply line 119 and the second reaction gas supply line 129 in a feeding step, thereby playing a part in facilitating the movement of the first reaction gas or diluting a concentration of the first or second reaction gas. Thus, an inert gas is called a carrier gas or a dilution gas.

Further, an inert gas is introduced into the reactor 105 through the first reaction gas supply line 119 and the second reaction gas supply line 129 in a purge step, thereby removing a first gas and a second gas or impurities existing in the reactor 105 via the exhaust line 169. Accordingly, an inert gas functions as a purge gas at the same time.

Meanwhile, when a capacitor electrode is made using an ALD thin film deposition method, TiN of from about 150 Å—up to about 250 Å can be deposited.

The first inert gas supply line 139 supplies an inert gas to the first reaction gas supply line 119, and the second inert gas supply line 149 supplies an inert gas to the second reaction gas supply line 129. The purge gas supply portion 150 supplies a purge gas to the first reaction gas supply line 119 and/or the second reaction gas supply line 129 only in a purge step. Further, the purge gas supply line 159 connects the purge gas supply portion 150 to the first reaction gas supply line 119 and/or the second reaction gas supply line 129.

A purge gas can be supplied to both the first reaction gas supply line 119 and the second reaction gas supply line 129. Alternatively, a purge gas can be supplied to only one of the first reaction gas supply line 119 and the second reaction gas supply line 129. In the present exemplary embodiment, a purge gas is supplied to both the first reaction gas supply line 119 and the second reaction gas supply line 129.

Furthermore, while a purge gas is introduced into the reactor 105 through the first reaction gas supply line 119 and the second reaction gas supply line 129, a purge gas can be directly introduced into the reactor 105. In the case of directly supplying a purge gas, a separate inlet (not shown) for the purge gas supply line 159 can be included in the reactor 105.

The purge gas supply portion 150 includes a fourteenth valve V14 for enabling or disabling the flow of a purge gas, a first purge gas MFC 155 for controlling the flow rate of a purge gas supplied to the first reaction gas supply line 119 passing through the fourteenth valve V14, and an eleventh valve V11 for enabling or disabling the flow of the purge gas controlled by the first purge gas MFC 155. Furthermore, the purge gas supply portion 150 includes a second purge gas MFC 156 for controlling the flow rate of a purge gas supplied to the second reaction gas supply line 129 passing through the fourteenth valve V14 and a twelfth valve V12 for enabling or disabling the flow of the purge gas controlled by the second purge gas MFC 156.

A mass flow controller or a needle valve, an air valve or the like, can be used as the first purge gas MFC 155 and the second purge gas MFC 156. Any apparatus that is generally used to control the flow rate can be used as the first purge gas MFC 155 and the second purge gas MFC 156, and the present invention is not limited to the above examples. In addition, the first purge gas MFC 155 and the second purge gas MFC 156 are controlled individually. Furthermore, if desired, the first purge gas MFC 155 and the second purge gas MFC 156 can be controlled by the same purge gas MFC.

In addition, the purge gas supply portion 150 is placed between the fourteenth valve V14 and a purge gas supply source and may further include a pressure adjusting portion 152 for constantly maintaining a pressure at an output end, if necessary.

The pressure adjusting portion 152 is generally adjusted with a regulator used for gas supply. The pressure adjusting portion 152 can be installed at an end of a gas supply line for supplying an inert gas, such as air and/or hydrogen, or the like. It is preferable that the pressure adjusting portion 152 includes an external safety valve which is self-controllable, and the body and filter of the pressure adjusting portion 152 be fabricated of a metal such as brass or bronze. Further, since a purge gas can be introduced into the reactor 105 at a pressure of about 60 psi, it is also preferable that the maximum pressure of an inlet of the pressure adjusting portion 152 is about 100 psi or more.

It is desirable for a first connecting portion 117 for connecting the first reaction gas supply line 119 and/or the second reaction gas supply line 129 to the purge gas supply line 159 to be as close as possible to a second connecting portion 118 for connecting the first reaction gas supply line 119 and/or the second reaction gas supply line 129 to the reactor 105. A distance between the first connecting portion 117 and the second connecting portion 118 is preferably within the range of from about 20 cm up to about 50 cm, and is more preferably about 30 cm. Further, it is advantageous for the eleventh valve V11 and the twelfth V12 to be as close as possible to the first connecting portion 117. A distance between the eleventh and twelfth valves V11 and V12 and the first connecting portion 117 is within the range of from about 20 cm up to about 40 cm, and is more preferably about 30 cm. That is, it is preferable that the eleventh and twelfth valves V11 and V12 are as close as possible to the reactor 105.

If the purge step is reached in a state in which a purge gas is filled up to the front ends of the eleventh and twelfth valves V11 and V12, the purge gas can approach the reactor 105 in a short amount of time, thereby making it possible to minimize the cycle time.

A third bypass line 199 allows a purge gas to flow directly to the exhaust line 169 without passing through the reactor 105. Further, the third bypass line 199 may include the fourteenth valve V14 for enabling or disabling the flow of a purge gas.

A purge gas can be at least one among N₂, Ar and Ne, but is not limited thereto.

In either case where the purge gas supply portion 150 operates only in the purge step or where the purge gas supply portion 150 additionally includes the purge gas supply line 159, the purge gas supply portion 150 has the following advantages.

A large number of improvement measures for shortening the cycle time may be taken. When the cycle time is shortened by shortening the time required in a feeding step, the time for which the first reaction gas and the second reaction gas are deposited on a surface of the substrate is not sufficient, which results in poor step coverage. Further, when the purge step is shortened, the first reaction gas and the second reaction gas can mix with each other, which results in the first reaction gas and the second reaction gas not reacting on the substrate surface. Accordingly, although the time required in the purge step is shortened, an ALD thin film deposition apparatus capable of increasing efficiency of the purge step and a thin film deposition method using the ALD thin film deposition apparatus are required. A measure for shortening the cycle time without separately providing the purge gas supply portion 150 and the purge gas supply line 159 will now be described.

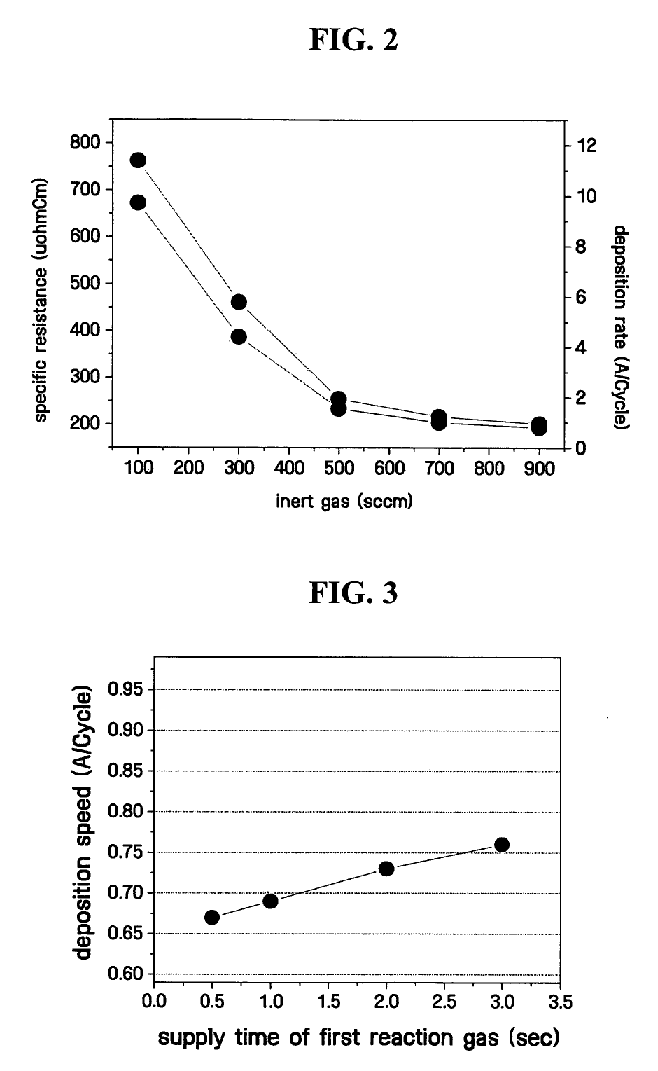

FIG. 2 is a graph showing changes in specific resistance according to an increase in the flow rate of an inert gas. FIG. 3 is a graph showing changes in a deposition speed according to the duration of supply time of the first reaction gas.

An internal pressure of the reactor 105 is about 3 torr and a temperature of the substrate block 103 is about 500° C. A purge step, a first reaction gas feeding step, a purge step and a second reaction gas feeding step are performed for about 2 seconds, 1 second, 2 seconds and 0.5 second, respectively. The first reaction gas is supplied at a flow rate of about 10 sccm and the second reaction gas is supplied at a flow rate of about 30 sccm. The first reaction gas, the second reaction gas and an inert gas are, for example, TiCl₄, NH₃ and Ar, respectively. Hereinafter, the purge step, the first reaction gas feeding step, the purge step and the second reaction gas feeding step are referred to as 1 cycle.

Referring to FIG. 2, the higher the flow rate of the inert gas, the lower the deposition speed per cycle and the lower the specific resistance at the same thickness (250 Å).

In the ALD thin film deposition method, unlike a CVD thin film deposition method, a formed thin film has low specific resistance, a thin film deposition speed is constant irrespective of supply of a reaction gas, and the thickness of the thin film can be decided according to the number of cycles. Further, a general ALD thin film deposition method has a deposition speed of about 0.3-0.4 Å per cycle.

Accordingly, the higher the flow rate of the inert gas, the better the characteristics of the ALD thin film deposition.

However, referring to FIG. 3, as the supply time of the first reaction gas becomes longer, a thin film deposition speed per cycle somewhat increases. It is advantageous for the ALD process to strengthen the purge step by increasing the flow rate of an inert gas. However, process pressure within the reactor 105 is typically reduced for attaining better characteristics.

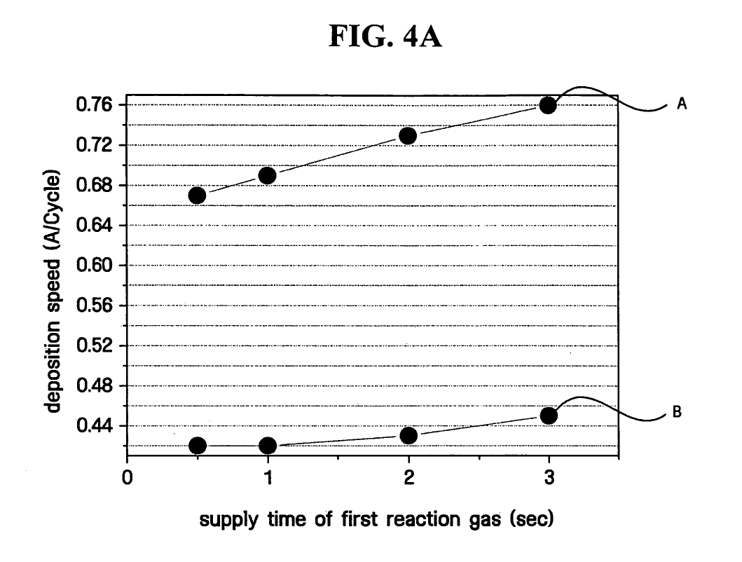

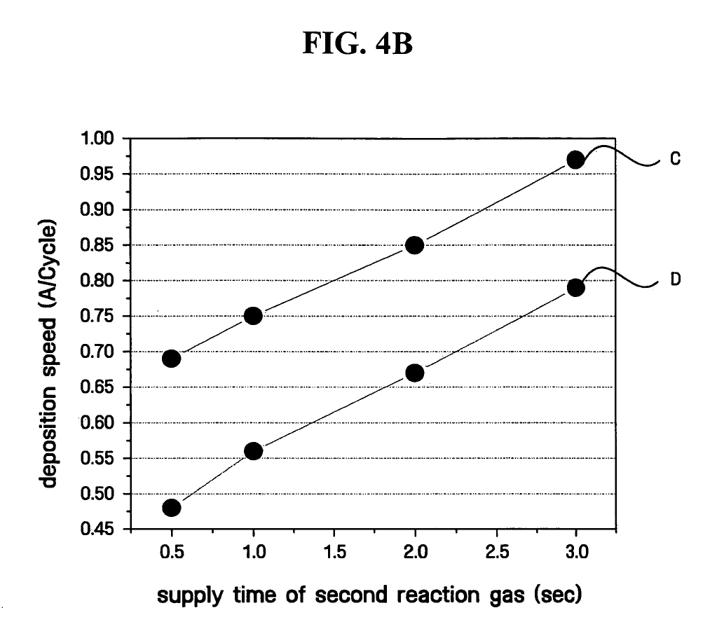

FIG. 4A is a graph showing changes in a deposition speed according to the duration of supply time of the first reaction gas when a process pressure within the reactor 105 is reduced. FIG. 4B is a graph showing changes in a deposition speed according to the duration of supply time of the second reaction gas when a process pressure within the reactor 105 is reduced. All the conditions except the reduction in the process pressure among the conditions of the ALD thin film deposition process are similar to those in FIGS. 2 and 3.

Referring to FIGS. 4A and 4B, the purge efficiency over supply time of the first reaction gas where process pressure within the reactor 105 is about 1 torr (referred to as case B) is better than that in a case where a process pressure is about 3 torr (referred to as case A). Likewise, the purge efficiency over supply time of the second reaction gas in a case where a process pressure is about 1 torr (referred to as a case D) is better than that in a case where a process pressure is about 3 torr (referred to as a case C). However, it can be seen that the deposition speed per cycle is not constant and increases over supply time of the first and second reaction gases.

Table 1 shows characteristics of the ALD thin film deposition according to changes in process conditions when process pressure within the reactor 105 is further reduced (to about 0.5 torr).

The process conditions are as follows. Each step of 1 cycle is performed for about 1 second, 0.5 second, 2 seconds and 0.5 second, respectively; the first reaction gas is supplied at a flow rate of about 10 sccm and the second reaction gas is supplied at a flow rate of about 30 sccm; and a process pressure within the reactor 105 is about 0.5 torr. In Table 1, a value of an inert gas indicates the flow rate of an inert gas in the purge step. Further, Rs means a value obtained by dividing the resistance of an ALD thin film by unit area. The values in parentheses under the columns of Rs and Thickness indicate dispersions of Rs and the thickness of the ALD thin film as percentages. In particular, Table 1 shows results measured at 49 points of the ALD thin film in the present experiment.

TABLE 1

| | | | | | Specific | Deposition | |
|---|---|---|---|---|---|---|---|
| Inert Gas | | | Thickness | | Resistance | Speed | |
| (sccm) | Rs | | (Å) | | (uΩcm) | (Å/cycle) | Remark |
| 100/100 | 359 | (60.2%) | 240 | (25.7%) | 865 | 0.68 | 12 failures |
| 300/300 | 511 | (69.1%) | 136 | (9.5%) | 698 | 0.38 | 13 failures |
| 500/500 | 1014 | (62.6%) | 85 | (10.8%) | 870 | 0.24 | 13 failures |
| 700/700 | 2575 | (54.4%) | 59 | (14.0%) | 1538 | 0.16 | 24 failures |
| 900/900 | 27342 | (58.8%) | 37 | (39.9%) | 10344 | 0.10 | 32 failures |

Referring to Table 1, it can be seen that the deposition speed per cycle is reduced as the flow rate of the inert gas increases. However specific resistance is significantly increased. Further, it can be seen that Rs is rapidly increased at an edge portion among the measured 49 points of the ALD thin film, suggesting a considerable number of failures were created.

If the process pressure is reduced to about 0.5 torr and the flow rate of the inert gas is increased for increasing the purge efficiency, partial pressures of the first reaction gas (TiCl₄) and the second reaction gas (NH₃) are rapidly reduced and a TiN thin film is not well formed.

TABLE 2

| | | | | | Specific | Deposition | |
|---|---|---|---|---|---|---|---|
| Inert Gas | | | Thickness | | Resistance | Speed | |
| (sccm) | Rs | | (Å) | | (uΩcm) | (Å/cycle) | Remark |
| 100/100 | 335 | (33.4%) | 353 | (28.7%) | 1185 | 0.95 | — |
| 300/300 | 535 | (42.1%) | 180 | (9.7%) | 965 | 0.51 | — |
| 500/500 | 566 | (14.8%) | 127 | (2.5%) | 723 | 0.35 | — |
| 700/700 | 1049 | (27.2%) | 95 | (6.1%) | 1001 | 0.27 | — |
| 900/900 | 1769 | (70.3%) | 72 | (9.3%) | 1275 | 0.20 | 15 failures |

Table 2 indicates characteristics of the ALD thin film deposition according to changes in a process condition. When a process pressure within the reactor 105 is slightly increased (to about 0.7 torr). Except for the process pressure of 0.7 torr, the process conditions in Table 2 are the same as those in the Table 1.

Referring to Table 2, it can be seen that characteristics of the ALD thin film deposition are optimum when the flow rate of the inert gas is 500/500 sccm from the standpoint of specific resistance and the dispersions of Rs and thin film thickness.

TABLE 3

| Second | | | | | Specific | Deposition |
|---|---|---|---|---|---|---|
| Reaction | Inert Gas | | | Thickness | Resistance | Speed |
| gas (sccm) | (sccm) | Rs | | (Å) | (uΩcm) | (Å/cycle) |
| 10 | 500/500 | 412 | (21.6%) | 120 (3.5%) | 506 | 0.34 |
| 30 | | 134 | (6.6%) | 199 (4.0%) | 268 | 0.56 |
| 50 | | 112 | (6.9%) | 214 (4.5%) | 242 | 0.61 |

Table 3 shows changes in specific resistance according to an increase in the flow rate of the second reaction gas (NH₃) under 500/500 sccm conditions.

Referring Table 3, specific resistance is reduced as the flow rate of the second reaction gas increases, and Rs and the thin film thickness remain almost constant in a saturation range after the flow rate of the second reaction gas is 30 sccm.

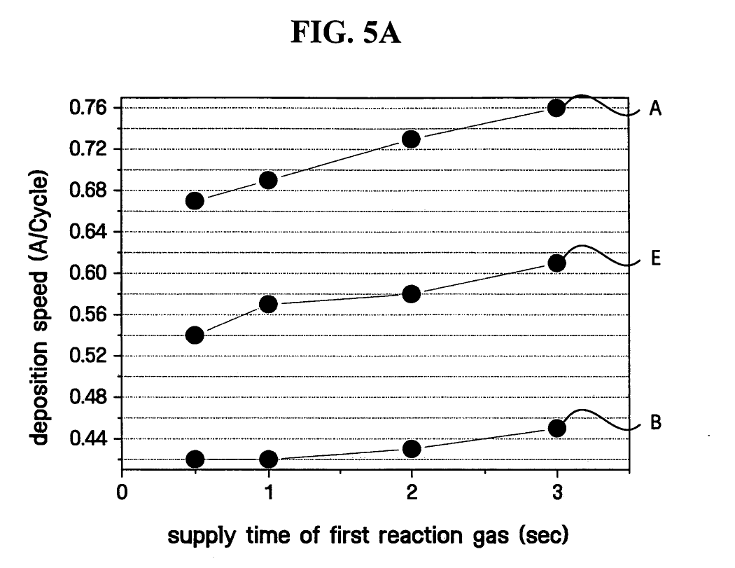

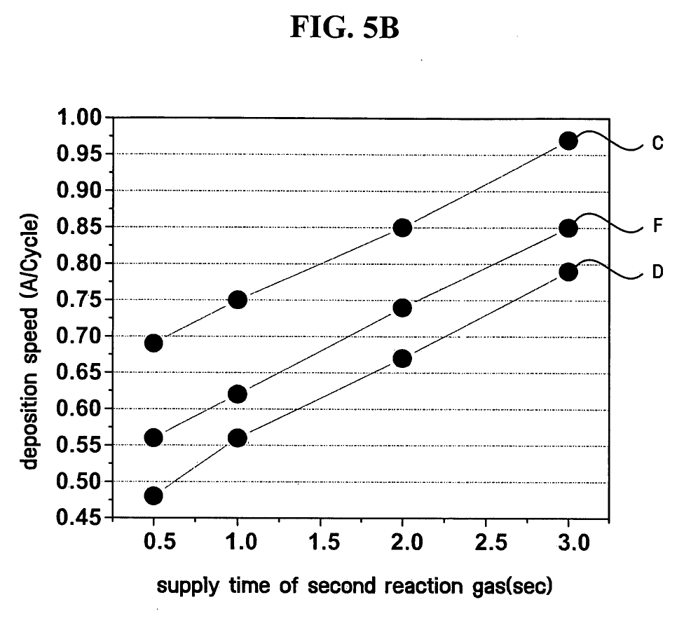

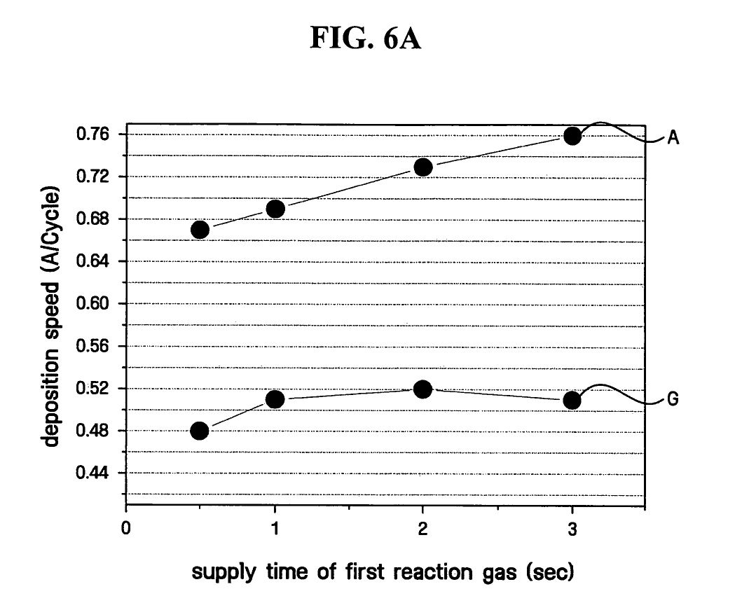

FIG. 5A is a graph showing changes in a deposition speed according to the duration of supply time of the first reaction gas under the 500/500 sccm conditions of Table 3. FIG. 5B is a graph showing changes in a deposition speed according to the duration of supply time of the second reaction gas under the 500/500 sccm conditions of Table 3.

Referring to FIGS. 5A and 5B, it can be seen that the purge efficiency where process pressure within the reactor 105 is about 0.7 torr (referred to as a case E) is better than that of case A where a process pressure is about 3 torr and is less than that of case B where a process pressure is about 1 torr according to the duration of supply time of the first reaction gas. Likewise, it can be seen that the purge efficiency of a case where a process pressure is about 0.7 torr (referred to as a case F) is better than that of case C where a process pressure is about 3 torr and is less than that of case D where a process pressure is about 1 torr according to the duration of supply time of the second reaction gas. Further, it can be seen that deposition speed per 1 cycle can be increased according to the extension of supply time of the first and second reaction gases.

Accordingly, it can be understood from the above experimental results that in order to increase the purge efficiency, the flow rate of the inert gas can be increased in the purge step even if the time used for the purge step is shortened. As described above, the inert gas can be continuously supplied in the first reaction gas feeding step, the second reaction gas feeding step and the purge step. However, use of a gas supply system controlled per second makes it quite difficult to increase or reduce the flow rate of the inert gas in units of seconds. Thus, an inert gas supply line exclusively used for the purge step, which supplies an inert gas in only the purge step, can be effectively employed. In the present invention, the purge gas supply portion 150 and the purge gas supply line 159 can be the inert gas supply line exclusively used for gas purge.

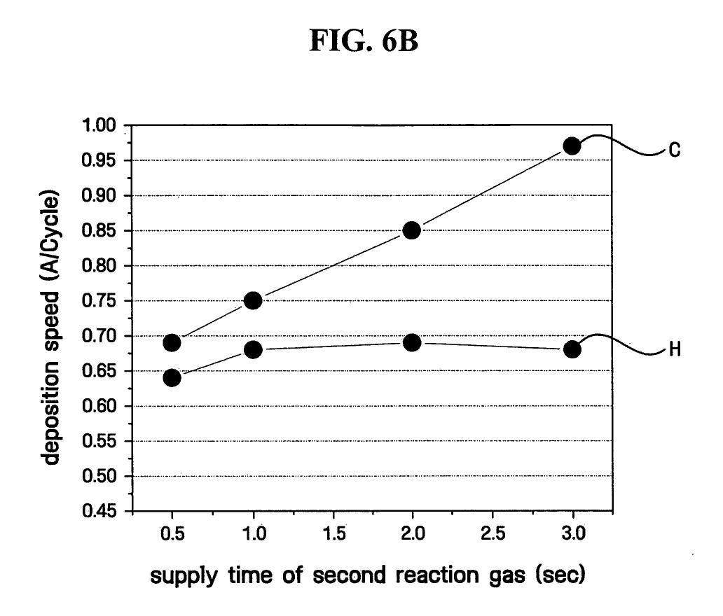

FIGS. 6A and 6B are graphs showing changes in deposition speed according to the duration of supply time of the first and second reaction gases when using the ALD thin film deposition apparatus according to the present invention.

Referring to FIGS. 6A and 6B, it can be seen that there can be a difference between case A and case G using the ALD thin film deposition apparatus according to this embodiment of the present invention, and a difference between case C and case H using the ALD thin film deposition apparatus according to this embodiment of the present invention. These differences can occur when there is an increase in the supply time of the first and second reaction gases, even if the process pressures are the same, i.e., about 3 torr. That is, if a purge gas is supplied through the purge gas supply line 159 according to this embodiment of the present invention, the deposition speed per cycle is constantly maintained regardless of the supply time of the first and second reaction gases.

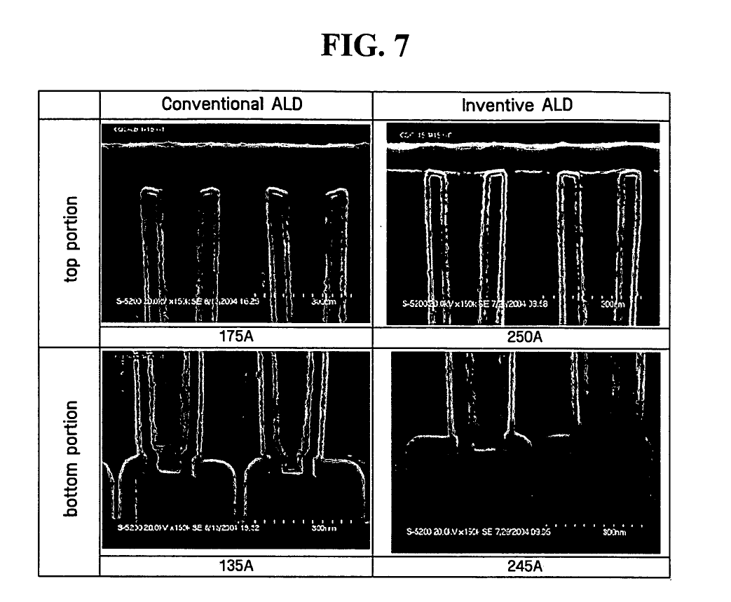

FIG. 7 is a cross-sectional view of an upper electrode of a capacitor fabricated using the ALD thin film deposition apparatus according to this embodiment of the present invention, photographed by a scanning electron microscope (SEM).

The SEM uses electrons as incident light and has an analysis depth of about 100 Å and a minimum analysis area of about 10 Å. The sensitivity of the SEM is about 100 ppm. If a cross section of a part is taken using the SEM, the surface shape, the element composition and the like can be determined.

Photographs of a top portion and a bottom portion of the upper electrode of the capacitor are shown in FIG. 7. In FIG. 7, the left photograph is of a capacitor fabricated using a conventional ALD thin film deposition apparatus, and the right photograph is of a capacitor fabricated using the ALD thin film deposition apparatus according to this embodiment of the present invention.

An experiment for thin film deposition is carried out using the ALD thin film deposition apparatus according the present invention based on a deposition thickness of about 250 Å. In the conventional ALD thin film deposition apparatus, the top portion is deposited to a thickness of about 175 Å and the bottom portion is deposited to a thickness of about 135 Å. In the ALD thin film deposition apparatus according to the present invention, the top portion is deposited to a thickness of about 250 Å and the bottom portion is deposited to a thickness of about 245 Å.

Accordingly, it can be seen that step coverage in the conventional ALD thin film deposition apparatus is about 77% ((135/175)*100=77) and step coverage in the ALD thin film deposition apparatus according to the present invention is about 98% ((245/250)*100=98). Further, it can be seen that the loading effect in the conventional ALD thin film deposition apparatus is 70% ((135/250)*100=70) and the loading effect in the ALD thin film deposition apparatus according to the present invention is 100% ((250/250)*100=100).

Accordingly, the capacitor in which the step coverage and the loading effect are excellent can be fabricated using the ALD thin film deposition apparatus according to this embodiment of the present invention.

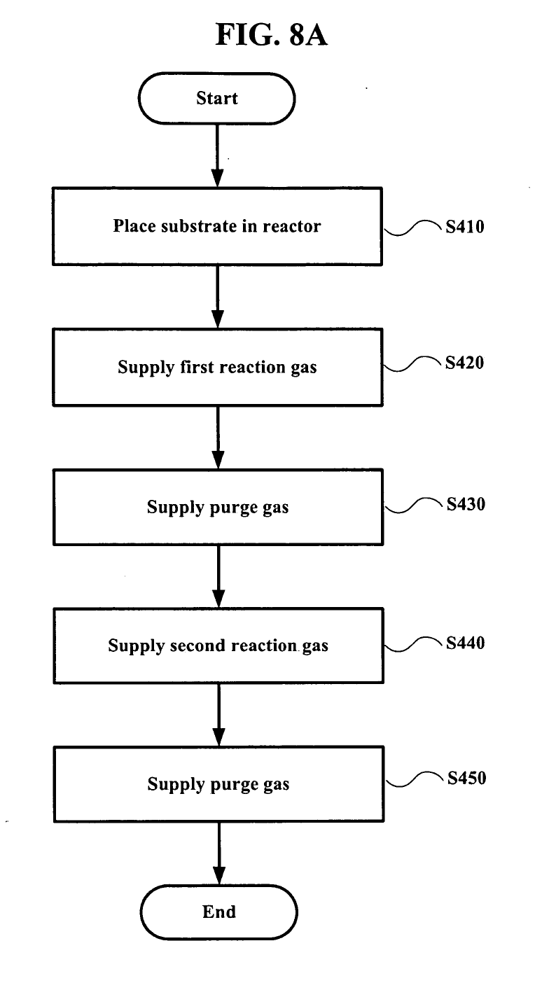

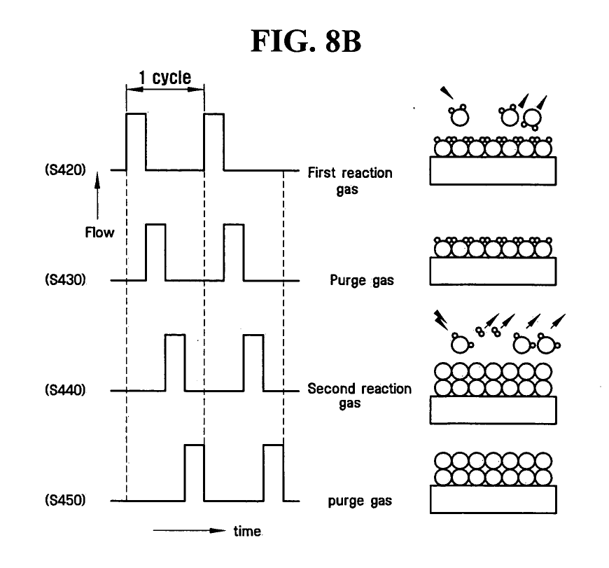

FIG. 8A is a flowchart showing a thin film deposition method using the ALD thin film deposition apparatus according to the present invention. FIG. 8B is a diagram for schematically explaining the supply of gas in the ALD thin film deposition method according to the present invention. Hereinafter, a process for depositing a TiN thin film on a substrate will be described. TiCl₄, NH₃ and Ar are used as the first reaction gas, the second reaction gas and an inert gas, respectively. TiCl₄ in a liquid state is received in a bubbler.

Referring to FIGS. 8A and 8B, a substrate is placed in a reactor of the ALD thin film deposition apparatus (100 of FIG. 1) according to the present invention, in operation S410. The substrate is transferred to the reactor by a robot arm of a transfer portion (not shown), and the substrate is placed on a substrate block.

Next, the b2 valve Vb2, the third valve V3, the fifth valve V5 and the seventh valve V7 are opened for several seconds. As a result, the bubbled first reaction gas is filled up to the first valve V1; the second reaction gas is properly controlled by a second reaction gas MFC and then is filled up to the fourth valve V4; and supply of an inert gas is controlled by a first inert gas MFC and a second inert gas MFC and then is filled up to the sixth valve V6 and the eighth valve V8.

The sixth valve V6 and the eighth valve V8 are opened to supply the inert gas to the reactor. The internal pressure of the reactor before supplying the inert gas is between about 10⁻⁴—and 5×10⁻³ torr, and the internal pressure of the reactor after supplying the inert gas is from about 1 to about 10 torr.

The internal pressure of the reactor is maintained by properly controlling a throttle valve TV of an exhaust line by a pressure measuring portion installed in the reactor. Here, the sixth and eighth valves V6 and V8 can be opened after the fifth and seventh valves V5 and V7 are opened so that the gas within the reactor may not flow backwards through the sixth and eighth valves V6 and V8 when they are suddenly opened. Next, the first reaction gas is introduced into the reactor in operation S420. That is, the second valve V2 is opened so that the first reaction gas together with the inert gas are introduced into the reactor through the first reaction gas supply line for a predetermined duration of time. Then, the second valve V2 is closed. As a result, a first reaction gas layer (TiCl₄ layer) is formed on the substrate. The inert gas functions as a carrier gas for carrying the first reaction gas to the reactor, or as a dilution gas for reducing a concentration of the first reaction gas.

It is preferable that the first reaction gas is supplied at a flow rate of from about 5 sccm to about 400 sccm, but the first reaction gas is not limited to this flow rate. Further, the supply time of the first reaction gas can be changed according to the thickness of the first reaction gas layer.

Next, the purge gas is introduced into the reactor in operation S430. Since the sixth and eighth valves V6 and V8 are kept open, the inert gas is continuously introduced into the reactor. As described above, a purge gas is supplied from the purge gas supply portion for increasing the flow rate of the inert gas. The purge gas is an inert gas such as He, Ne, or N₂. Accordingly, the purge gas supply portion is operated in only operation S430, increasing the flow rate of the inert gas within the reactor.

The first reaction gas layer is compressed on the substrate by the inert gas and the purge gas. The inert gas and the purge gas serve to remove the first reaction gas remaining within the reactor through the exhaust line.

The purge gas supply portion 150 can supply the purge gas at a flow rate of from about 500 up to about 10,000 sccm. Preferably, the purge gas supply portion 150 supplies the inert gas and the purge gas a plurality of times at the same rate as the flow rate of the first reaction gas or the second reaction gas. Further, the purge step can last for about 0.2 seconds up to about 4 seconds.

As described above, since the efficiency of the purge step is increased while the time required in the purge step is shortened, production efficiency can be increased and the ALD thin film with the excellent step coverage can be fabricated.

Next, the second reaction gas is introduced into the reactor in operation S440. That is, the fourth valve V4 is opened so that the second reaction gas together with the inert gas are supplied through the second reaction gas supply line for a predetermined duration of time and then the fourth valve V4 is closed. As a result, the second reaction gas layer (NH₃ layer) is formed on the first reaction gas layer (TiCl₄ layer).

It is preferable that the second reaction gas can be supplied at a flow rate of about 5 up to about 400 sccm, but the second reaction gas is not limited to this flow rate. Further, the supply time of the second reaction gas is changed according to the thickness of the second reaction gas layer.

Next, the purge gas is introduced into the reactor in operation S450. Similarly to operation S430, since the sixth and eighth valves V6 and V8 are kept open, the inert gas can be continuously introduced into the reactor. Further, a purge gas can be supplied from the purge gas supply portion.

Specifically, a TiN+NH₃ layer can be formed through the supply of the first and second reaction gases. Next, the first reaction gas is again supplied to the TiN+NH₃ layer for the continuous growth of the thin film. As a result, the TiN+NH₃ layer is changed into a TiN+TiN+TiCl₄ layer. Subsequently, a TiN+TiN+TiN+NH₃ layer is formed by supplying the second reaction gas again. As described above, the thickness of the TiN thin film on the substrate can be controlled by alternately supplying the first reaction gas and the second reaction gas. Further, the first reaction gas and the second reaction gas can be supplied irrespective of the order of supply.

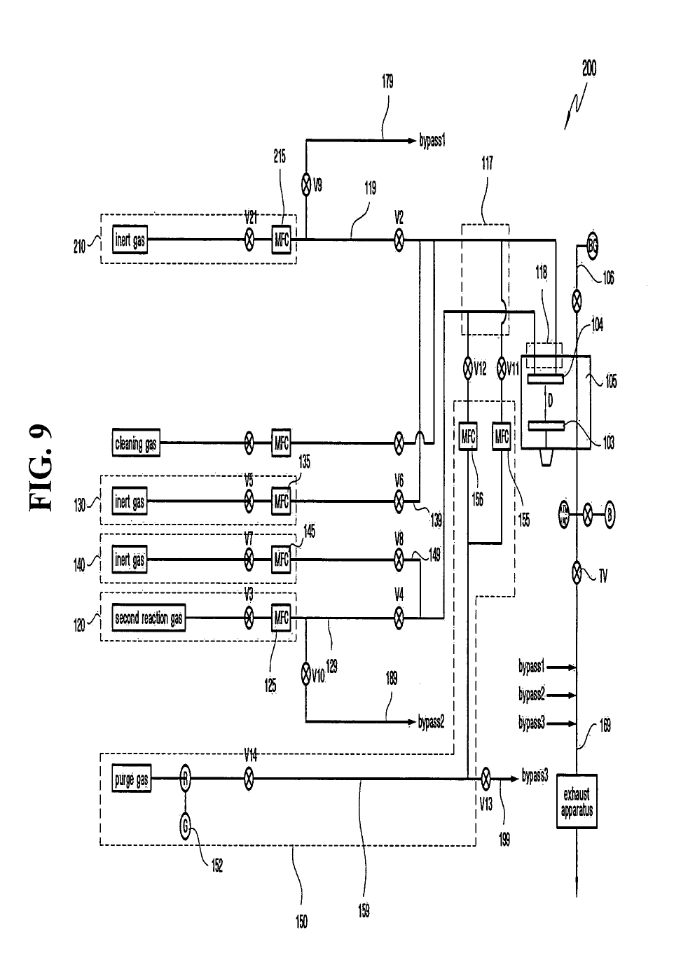

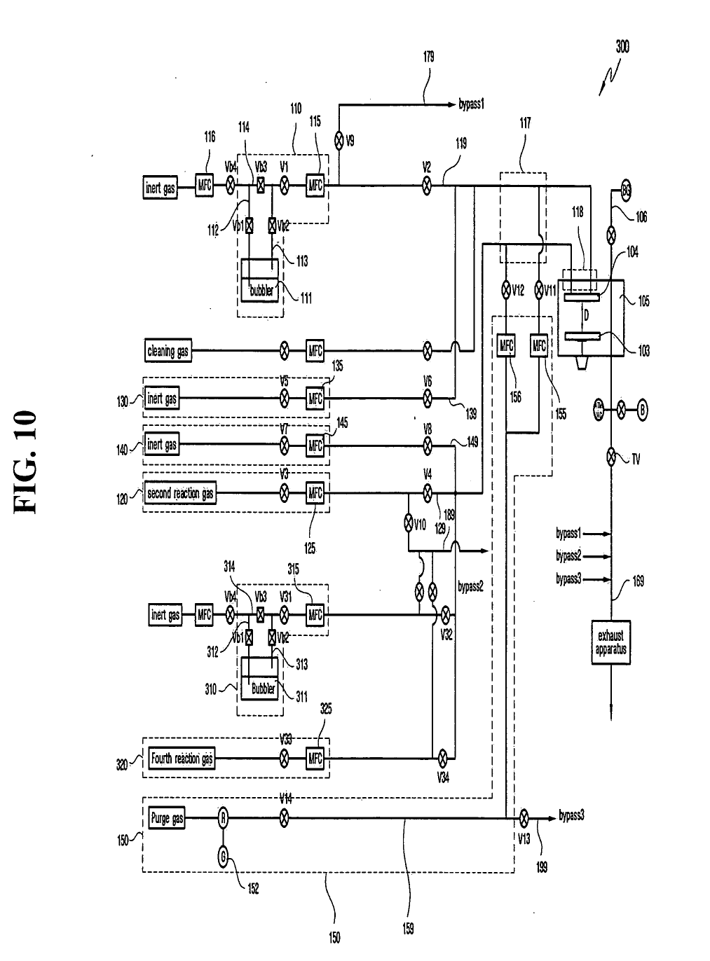

Compared to the ALD thin film deposition apparatus 200 according to the embodiment shown in FIG. 1, the ALD thin film deposition apparatus 200 shown in FIG. 9 includes a first reaction gas supply portion 210 instead of the first reaction gas supply portion 110. The first reaction gas supply portion 210 includes a twenty-first valve V21 for enabling or disabling the flow of a first reaction gas and a first reaction gas MFC 215 for controlling the flow rate of the first reaction gas passing through the twenty-first valve V21. The first reaction gas supply portion 210 is connected to a second valve V2. The same reference numerals as those shown in FIG. 1 denote the same elements, and thus, a detailed description thereof will not be given.

A WN thin film can be deposited using the ALD thin film deposition apparatus 200 according to the illustrative embodiment of the present invention. In this case, the first reaction gas is WF₆ gas and the second reaction gas is a gas containing N, for example, NH₃. However, the present invention is not limited thereto and can be modified within the spirit and scope of the present invention.

An ALD thin film deposition method will be now described by way of example. First, WF₆ gas and an inert gas are supplied together and WF₆ gas is removed with the passage of a predetermined duration of time. As a result, a WF₆ gas layer is formed on the substrate and the WF₆ gas layer is compressed by an inert gas and a purge gas which are continuously introduced into a reactor 105.

Next, NH₃ gas and an inert gas are supplied together and NH₃ gas is removed with the passage of a predetermined duration of time. As a result, a NH₃ gas layer is formed on the WF₆ gas layer and then a WN+NH₃ layer is formed by the reaction between the NH₃ gas layer and the WF₆ gas layer. A WN thin film having a desired thickness can be obtained by repeating the above-described processes.

Compared to the ALD thin film deposition apparatus 100 according to the embodiment shown in FIG. 1, the ALD thin film deposition apparatus 300 according to the illustrative embodiment of the present invention further includes a third reaction gas supply portion 310, a third reaction gas supply line 319, a fourth reaction gas supply portion 320 and a fourth reaction gas supply line 329.

The third reaction gas supply portion 310 includes a bubbler 311 for gasifying a third reactive material, a third reaction gas MFC 315 for controlling the flow rate of the third reaction gas, and a thirty-first valve V31 which is placed between the bubbler 311 and the third reaction gas MFC 315 and enables or disables the flow of the third reaction gas. The third reaction gas supply portion 310 further includes a thirty-second valve V32 for enabling or disabling the flow of the third reaction gas controlled by the third reaction gas MFC 315.

The fourth reaction gas supply portion 320 includes a thirty-third valve V33 for enabling or disabling the flow of a fourth reaction gas and a fourth reaction gas MFC 325 for controlling the flow rate of the fourth reaction gas passing through the thirty-third valve V33. The fourth reaction gas supply portion 320 further includes a thirty-fourth valve V34 for enabling or disabling the flow of the fourth reaction gas controlled by the fourth reaction gas MFC 325. The same reference numerals as those shown in FIG. 1 denote the same elements, and thus, a detailed description thereof will be omitted.

TiN, TaN, Ti and TiAlN thin films can be deposited using the ALD thin film deposition apparatus 300 according to this embodiment of the present invention. In this case, the third reaction gas is TMA gas and the fourth reaction gas is H₂ gas. However, the present invention is not limited thereto and can be modified within the sprit and scope of the present invention.

An ALD thin film deposition method according to still another embodiment of the present invention is substantially the same as that according to one embodiment of the present invention, and thus a description thereof is omitted.

A sequential flow deposition (SFD) thin film deposition apparatus as well as the ALD thin film deposition apparatus can be applied to a thin film deposition method within the scope of the present invention.

Since an inert gas supplied from a first reaction gas supply portion and a second reaction gas supply portion can be continuously supplied at a predetermined flow rate, the inert gas can be used as a carrier gas or a dilution gas. However, it may not be sufficient to use the inert gas as a purge gas. Accordingly, a purge step can be performed at a flow rate different to that of the carrier gas by including a separate purge gas supply portion, thereby making it possible to widen the width of the recipe control. Further, the characteristics of an ALD thin film can be adjusted as determined by the user.

As described above, an ALD thin film deposition apparatus according to the present invention and an ALD thin film deposition method using the same provide at least the following advantages.

First, the efficiency of a purge step can be increased by supplying a separate purge gas regardless of whether the time used for the purge step is shortened.

Second, characteristics of an ALD thin film can be increased. In particular, a conductive thin film with excellent step coverage can be formed.

Third, a recipe for the ALD thin film deposition can be controlled as determined by the user.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. An atomic layer deposition (ALD) thin film deposition apparatus comprising:
a reactor including a support for placing at least one substrate thereon and a member from which gases are sprayed;
a first reaction gas supply line coupled with a first reaction gas supply portion which allows a first reaction gas to flow from the first reaction gas supply portion to the reactor;
a second reaction gas supply line coupled with a second reaction gas supply portion which allows a second reaction gas to flow from the second reaction gas supply portion to the reactor for reacting with the first reaction gas;
a purge gas supply line coupled with a purge gas supply portion and allows a purge gas to flow from the purge gas supply portion to the reactor for conducting a purge step; and
an exhaust line which exhausts a gas from within the reactor to a location outside the reactor.

2. The ALD thin film deposition apparatus of claim 1, wherein the support and the member are separated by a predetermined distance of from about 5 mm to about 25 mm.

3. The ALD thin film deposition apparatus of claim 1, wherein the purge gas supply line is connected to the first reaction gas supply line and/or the second reaction gas supply line.

4. The ALD thin film deposition apparatus of claim 1, wherein the purge gas supply line is directly connected to the reactor.

5. The ALD thin film deposition apparatus of claim 1, wherein the first reaction gas comprises TiCl₄ or Ta and the second reaction gas comprises NH₃.

6. The ALD thin film deposition apparatus of claim 1, wherein the first reaction gas supply portion includes a bubbler for gasifying a first reactive material, a first reaction gas mass flow controller (MFC) for controlling the flow rate of the first reaction gas, and a first valve which is placed between the bubbler and the first reaction gas MFC and enables or disables the flow of the first reaction gas.

7. The ALD thin film deposition apparatus of claim 6, wherein the first reaction gas supply portion further includes a second valve which is placed between the first reaction gas MFC and the reactor on the first reaction gas supply line and enables or disables the flow of the first reaction gas controlled by the first reaction gas MFC.

8. The ALD thin film deposition apparatus of claim 1, wherein the second reaction gas supply portion includes a third valve for enabling or disabling the flow of the second reaction gas and a second reaction gas MFC for controlling the flow rate of the second reaction gas passing through the third valve.

9. The ALD thin film deposition apparatus of claim 8, wherein the second reaction gas supply portion further includes a fourth valve which is placed between the second reaction gas MFC and the reactor on the second reaction gas supply line and enables or disables the flow of the second reaction gas controlled by the second reaction gas MFC.

10. The ALD thin film deposition apparatus of claim 1, further comprising a first inert gas supply line which is connected with a first inert gas supply portion and allows an inert gas to flow from the first inert gas supply portion to the first reaction gas supply line.

11. The ALD thin film deposition apparatus of claim 10, wherein the first inert gas supply portion includes a fifth valve for enabling or disabling the flow of an inert gas and a first inert gas MFC for controlling the flow rate of the inert gas passing through the fifth valve.

12. The ALD thin film deposition apparatus of claim 11, wherein the first inert gas supply portion further includes a sixth valve which is placed close to the reactor between the first inert gas MFC and the reactor on the first inert gas supply line and enables or disables the flow of an inert gas controlled by the first inert gas MFC.

13. The ALD thin film deposition apparatus of claim 1, further comprising a second inert gas supply line which is coupled with a second inert gas supply portion and allows an inert gas to flow from the second inert gas supply portion to the second reaction gas supply line.

14. The ALD thin film deposition apparatus of claim 13, wherein the second inert gas supply portion includes a seventh valve for enabling or disabling the flow of an inert gas and a second inert gas MFC for controlling the flow rate of the inert gas passing through the seventh valve.

15. The ALD thin film deposition apparatus of claim 14, wherein the second inert gas supply portion further includes an eighth valve which is placed between the second inert gas MFC and the reactor on the second inert gas supply line and enables or disables the flow of an inert gas controlled by the second reaction gas MFC.

16. The ALD thin film deposition apparatus of claim 1, further comprising a first bypass line which includes a ninth valve for enabling or disabling the flow of the first reaction gas and allows the first reaction gas to flow directly to the exhaust line without passing through the reactor.

17. The ALD thin film deposition apparatus of claim 1, further comprising a second bypass line which includes a tenth valve for enabling or disabling the flow of the second reaction gas and allows the second reaction gas to flow directly to the exhaust line without passing through the reactor.

18. The ALD thin film deposition apparatus of claim 3, wherein the flow rates of the purge gas supplied to the first reaction gas supply line and the second reaction gas supply line are independently controlled by a first purge gas MFC and a second purge gas MFC, respectively, placed on the purge gas supply line.

19. The ALD thin film deposition apparatus of claim 18, wherein the purge gas supply portion includes an eleventh valve and a twelfth valve which are placed close to the reactor at an interval of a predetermined distance on the first reaction gas supply line and the second reaction gas supply line, and enable or disable the flow of the purge gas controlled respectively by the first purge gas MFC and the second purge gas MFC.

20. The ALD thin film deposition apparatus of claim 18, wherein the purge gas supply portion further includes a pressure adjusting portion which is placed between the first purge gas MFC and the second purge gas MFC and a purge gas supply source and constantly maintains a pressure of an output end.

21. The ALD thin film deposition apparatus of claim 3, wherein a first connecting portion for connecting the first reaction gas supply line and/or the second reaction gas supply line to the purge gas supply line is placed adjacent to a second connecting portion for connecting the first reaction gas supply line and/or the second reaction gas supply line to the reactor at a predetermined distance.

22. The ALD thin film deposition apparatus of claim 21, wherein the predetermined distance is from about 20 cm to about 50 cm.

23. The ALD thin film deposition apparatus of claim 21, wherein the eleventh and twelfth valves are placed adjacent to the first connecting portion at an interval of a predetermined distance.

24. The ALD thin film deposition apparatus of claim 23, wherein the predetermined distance is from about 20 cm to about 40 cm.

25. The ALD thin film deposition apparatus of claim 1, wherein the purge gas is N₂ and/or Ar and/or Ne.

26. The ALD thin film deposition apparatus of claim 1, further comprising a third bypass line which includes a thirteenth valve for enabling or disabling the flow of the purge gas and allows the purge gas to flow directly to the exhaust line without passing through the reactor.

27. The ALD thin film deposition apparatus of claim 1, wherein the first reaction gas supply portion includes a valve for enabling or disabling the flow of the first reaction gas and a first reaction gas MFC for controlling the flow rate of the first reaction gas passing through the valve.

28. The ALD thin film deposition apparatus of claim 27, wherein the first reaction gas is WF₆ and the second reaction gas is NH₃.

29. The ALD thin film deposition apparatus of claim 1, further comprising a third reaction gas supply line which is coupled with a third reaction gas supply portion and allows a third reaction gas to flow from the third reaction gas supply portion to the reactor exclusively with respect to the first reaction gas; and a fourth reaction gas supply line which is connected with a fourth reaction gas supply portion and allows a fourth reaction gas to flow from the fourth reaction gas supply portion to the reactor exclusively with respect to the first reaction gas.

30. The ALD thin film deposition apparatus of claim 29, wherein the third reaction gas supply line and the fourth reaction gas supply line are connected to the second reaction gas supply line.

31. The ALD thin film deposition apparatus of claim 29, wherein the third reaction gas supply portion includes a bubbler for gasifying a third reactive material, a third reaction gas MFC for controlling the flow rate of the third reaction gas, and a first valve which is placed between the bubbler and the third reaction gas MFC and enables or disables the flow of the third reaction gas.

32. The ALD thin film deposition apparatus of claim 29, wherein the fourth reaction gas supply portion includes a second valve for enabling or disabling the flow of the fourth reaction gas and a fourth reaction gas MFC for controlling the flow rate of the fourth reaction gas passing through the second valve.

33. The ALD thin film deposition apparatus of claim 29, wherein the third reaction gas is trimethylaluminum (TMA) and the fourth reaction gas is H₂.

34. An ALD thin film deposition method comprising:
placing at least one substrate on a support located within a reactor;
providing a member located within the reactor from which gases are sprayed;
supplying a first reaction gas to the reactor through a first reaction gas supply line;
supplying a first purge gas to the reactor through a purge gas supply line to the first reaction gas;
supplying a second reaction gas to the reactor through a second reaction gas supply line for reaction with the first reaction gas; and
supplying a second purge gas to the reactor through the purge gas supply line to the second reaction gas.

35. The ALD thin film deposition method of claim 34, wherein the supplying of the first reaction gas, the first purge gas, the second reaction gas and the second purge gas includes supplying an inert gas to the reactor through an inert gas supply line.

36. The ALD thin film deposition method of claim 34, wherein the purge gas is supplied at a flow rate of from about 500 sccm to about 10,000 sccm.

37. The ALD thin film deposition method of claim 35, wherein the flow rates of the inert gas and the purge gas are at least about two times greater than the flow rate of the first reaction gas or the flow rate of the second reaction gas.

38. The ALD thin film deposition method of claim 34, wherein the supply time for providing the purge gas is from about 0.2 seconds to about 4 seconds.
